(19) United States
(12) Patent Application Publication
(10) Pub. No.: US 2016/0141342 A1
(43) Pub. Date: May 19, 2016

(54) ARRAY SUBSTRATE AND MANUFACTURING METHOD THEREOF, AND DISPLAY APPARATUS

(71) Applicant: BOE TECHNOLOGY GROUP CO., LTD., Beijing (CN)

(72) Inventors: Jinzhong ZHANG, Beijing (CN); Zongmin TIAN, Beijing (CN)

(73) Assignee: Beijing Boe Optoeletronics Technology Co., Ltd.

(21) Appl. No.: 14/371,883

(22) PCT Filed: Dec. 12, 2013
(86) PCT No.: PCT/CN2013/089157

§ 371 Date: Jul. 11, 2014

(30) Foreign Application Priority Data
Sep. 25, 2013 (CN) 201310450908.8

(51) Int. Cl. H01L 27/32; H01L 29/423

(52) U.S. Cl. CPC H01L 27/3248; H01L 27/3262; H01L 29/42364; H01L 29/42384; H01L 27/3258; H01L 2227/323

(57) ABSTRACT

An array substrate and a manufacturing method thereof, and a display apparatus are provided. The array substrate may include a base substrate, a scan line, a data line arranged to cross each other on the base substrate, pixel units arranged in a matrix and defined by the scan lines and data lines, wherein a thin film transistor, a pixel electrode and a light emitting structure are disposed in the pixel unit, the pixel electrode is disposed above the layer where the thin film transistor is located, the region covered by the pixel electrode includes a region over the thin film transistor; the light emitting structure is disposed above the layer where the thin film transistor is located, and its covered region corresponds to the region covered by the pixel electrode.

### TECHNICAL FIELD

Embodiments of the present invention relate to a field of liquid crystal display technology, and in particular, to an array substrate and a manufacturing method thereof, and a display apparatus.

### BACKGROUND

Thin film transistor liquid crystal display (TFT-LCD) has advantages such as small volume, low power consumption, no irradiation, and so on, and is developed rapidly in recent years, and occupies a dominant position in a market of current flat panel display.

TFT-LCD is constituted by a liquid crystal display panel, a driving circuit, and a backlight module, wherein the liquid crystal display panel is an important portion of TFT-LCD. The liquid crystal display panel is formed by injecting liquid crystal between an array substrate and a color filter substrate, and sealing four edges by using seal agent, then respectively attaching polarizer having polarizing direction perpendicular to each other on the array substrate and the color filter substrate, and so on. Referring to FIGS. 1 and 2, FIG. 1 is a plan structural view of an array substrate in prior art, and FIG. 2 is a cross-sectional structural schematic view of the array substrate along the A-A1 direction in FIG. 1. It can be seen from FIGS. 1 and 2 that the array substrate comprises a plurality of pixel units arranged in a matrix, and each pixel unit comprises a light-transmitting region and a non-light-transmitting region, wherein a region defined by a dash line EE′ and a dash line CC′ is the light-transmitting region of the pixel region, and a region defined by a dash line CC′ and a dash line DD′ is the non-light-transmitting region of the pixel region. The non-light-transmitting region may comprise a scan line 101 and a data line 102 crossing with each other on a base substrate 100 and thin film transistors 10 arranged in a matrix. The thin film transistor 10 may comprise a gate electrode 103, a gate insulation layer 104, an active layer 105, a source 106 and a drain electrode 107. The light-transmitting region may comprise a pixel electrode 108.

The active layer 105 is generally formed by using amorphous silicon (a-Si) material, and thin film transistor formed by amorphous silicon material has advantages such as mature technology, low cost, simple process, good stability and so on; however, the thin film transistor formed by amorphous silicon material has a relatively poor characteristics, wherein the most basic parameters representing characteristics of the thin film transistor comprise: carrier mobility, threshold voltage, and subthreshold swing. With the development of display technology, thin film transistor formed by using poly silicon (p-Si) and thin film transistor formed by using metal oxide material have appeared, wherein the thin film transistor formed by using poly silicon material has advantages of high TFT characteristics, high carrier mobility and so on, however, the thin film transistor formed by using poly silicon material has an unstable characteristics and poor uniformity; the thin film transistor formed by using oxide material has advantages of relative high characteristics, good uniformity and so on, however, its production cost is high and manufacturing process is complicate.

With the requirement by the developing trend of high aperture ratio, high resolution and so on, there are various kinds of technologies which may be used to achieve a relatively high resolution, such as low temperature poly silicon thin film transistor technology, semiconductor oxide thin film transistor technology, fine technology reducing widths of gate line, source line and drain line, however, the improvement circumstance of the aperture ratio is not perfect, wherein the aperture ratio indicates a ratio of an area of the light-transmitting portion after removing the peripheral circuit region and the thin film transistor region of each pixel and the entire area of each pixel. With the development of organic light-emitting diode (OLED), OLED has been used to improve the aperture ratio of pixel, however, the OLED is a current driving device, and it needs relatively high carrier mobility, and a relatively higher aperture ratio can be obtained only if the OLED is driven by using low temperature poly silicon technology, however, since there exist problems such as poor uniformity, complicate process, low yield, and so on, the application of the solution of OLED driven by low temperature poly silicon technology still could not solve the problem of low aperture ratio well.

### SUMMARY

Embodiments of the present invention provide an array substrate and a manufacturing method thereof and a display apparatus, which may increase an aperture ratio of a pixel.

An embodiment of the present invention provides an array substrate, and the array substrate comprises: a plurality of pixel units arranged in a matrix, wherein each of the pixel units comprises a light-transmitting region and a non light-transmitting region, the light-transmitting region comprises a pixel electrode, and the non light-transmitting region comprises a thin film transistor, a scan line and a data line, wherein the pixel electrode is positioned above a layer where the thin film transistor is located, and the pixel electrode partially or entirely covers the non light-transmitting region; each of the pixel units further comprises a light emitting structure which is disposed above the layer where the thin film transistor is located and is disposed to be insulating from the pixel electrode, and a region covered by the light emitting structure corresponds to a region covered by the pixel electrode, and the light emitting structure is used to provide a backlight source.

In an embodiment, the light emitting structure may be connected with a common electrode line, and used as a common electrode of the array substrate, so as to further simplify manufacturing process and save production cost. In addition, a common electrode may be further added and disposed in the array substrate, and the common electrode may generate an electric field to drive molecules of a liquid crystal layer to generate deflection together with the pixel electrode.

In an embodiment, the light emitting structure may comprise a cathode disposed above the pixel electrode, a light emitting material layer disposed on the cathode, and an anode disposed on the light emitting material layer, wherein the anode may be connected to the common electrode line; or, the light emitting structure may comprise an anode disposed above the pixel electrode, a light emitting material layer disposed on the anode, and a cathode disposed above the light emitting material layer, wherein the anode may be connected to the common electrode line. Since two electrodes are disposed in the light emitting structure to drive the light emitting material layer to emit light, it removes the dependence of the light emitting structure on the thin film transistor having relatively high carrier mobility, and solve the problem that the thin film transistor with relative low carrier mobility could not be used to manufacture a display of high aperture ratio and high resolution.

In an embodiment, the light emitting structure may be located above the pixel electrode, wherein the light emitting structure is of slit shape, and the pixel electrode is of plate shape or slit shape; or the light emitting structure is located under the pixel electrode, the light emitting structure is of slit shape or plate shape, and the pixel electrode is of slit shape. By the above structure, a horizontal electric field may be formed between the light emitting structure and the pixel electrode, which drives liquid crystal molecules in the liquid crystal layer to generate rotation, so as to achieve displaying of the image.

In an embodiment, the gate insulation layer of the thin film transistor may have a thickness of about 6000˜8000 Å, and the thickness is about two times of a thickness of the gate insulation layer in a common thin film transistor. Increasing the thickness of the gate insulation layer may effectively reduce the coupling capacitance between the gate electrode and the source/drain electrode of the thin film transistor, so as to reduce power consumption of the thin film transistor.

In an embodiment, the array substrate may further comprise a passivation layer disposed between the layer where the thin film transistor is located and the pixel electrode, so that it is possible to form the pixel electrode above the thin film transistor, and at the same time, be used to protect the thin film transistor from being corroded; in addition, a via hole is further disposed in the passivation layer, so that the pixel electrode is electrically connected with the drain electrode of the thin film transistor by the via hole.

In an embodiment, the array substrate may further comprise a second passivation layer disposed between the pixel electrode and the light emitting structure, to isolate the pixel electrode from the light emitting structure.

In an embodiment, the thin film transistor may have a top-gate structure or a bottom-gate structure.

An embodiment of the present invention further provides a display apparatus, comprising the above array substrate.

An embodiment of the present invention further provides a method of manufacturing an array substrate, and the method may comprise: a step of forming a data line, a scan line and a pixel electrode and a step of forming a thin film transistor, wherein the pixel electrode is formed in a light-transmitting region of a pixel unit, and the thin film transistor, the scan line and the data line are formed in the non light-transmitting region, wherein the pixel electrode is located above a layer where the thin film transistor is located, and the pixel electrode partially or entirely covers the non-light-transmitting region; a step of forming a light emitting structure, wherein the light emitting structure is located above the layer where the thin film transistor is located, and is disposed to be insulated from the pixel electrode, and a region covered by the light emitting structure corresponds to a region covered by the pixel electrode, and is used to provide a backlight source.

In an embodiment, the step of forming the light emitting structure may comprise:

forming a pattern comprising a cathode; forming a pattern comprising a light emitting material layer on the pattern comprising the cathode; and forming a pattern comprising an anode on the pattern comprising the light emitting material layer;

alternatively, foaming a pattern comprising an anode; forming a pattern comprising a light emitting material layer on the pattern comprising the anode; and forming a pattern comprising a cathode on the pattern comprising the light emitting material layer.

Thus, the anode and the cathode used to drive the light emitting material layer to emit light are formed in the light emitting structure, and it removes the dependence of the light emitting structure on the thin film transistor having relatively high carrier mobility, and solves the problem that the thin film transistor with relative low carrier mobility could not be used to manufacture a display of high aperture ratio and high resolution.

In an embodiment, the method may further comprise: forming a passivation layer between the layer where the thin film transistor is located and the pixel electrode, so that it is possible to form the pixel electrode above the thin film transistor, and it is also possible to protect the thin film transistor from being corroded.

In an embodiment, the method may further comprise: forming a second passivation layer between the pixel electrode and the light emitting structure, to isolate the pixel electrode from the light emitting structure.

In an embodiment, the method may further comprise: forming a via hole at least in the passivation layer, so that the pixel electrode is electrically connected with the drain electrode of the thin film transistor by the via hole.

In the above array substrate and manufacturing method thereof, the region covered by the pixel electrode comprises the region over thin film transistor, and thus the region covered by the pixel electrode is increased, compared with the region covered by the pixel electrode in the prior art; meantime, since the light emitting structure functions as a backlight source, it cause that there is light ray passing through the region corresponding to the pixel electrode located over the thin film transistor, and the region may perform image displaying, which improves the aperture ratio of the pixel.

### BRIEF DESCRIPTION OF DRAWINGS

FIG. 1 is a plan structural schematic view of an array substrate in the prior art;

FIG. 2 is a sectional structural schematic view of the array substrate along a direction A-A1 in FIG. 1;

FIG. 3 is a plan structural schematic view of an array substrate provided by the first embodiment of the present invention;

FIG. 4 is a sectional structural schematic view of the array substrate along a direction B-B1 in FIG. 3;

FIG. 5 is a sectional structural schematic view of a light emitting structure in the array substrate provided by the first embodiment;

FIG. 6 is a sectional structural schematic view of an array substrate provided by a second embodiment of the present invention;

FIG. 7 is a sectional structural schematic view of an array substrate provided by a third embodiment of the present invention;

FIG. 8 is a sectional structural schematic view of a light emitting structure in a fourth embodiment;

FIG. 9 is a sectional structural schematic view of an array substrate completing the fabrication of a gate electrode;

FIG. 10 is a sectional structural schematic view of an array substrate completing the fabrication of a gate insulation layer;

FIG. 11 is a sectional structural schematic view of an array substrate completing the fabrication of an active layer;

FIG. 12 is a sectional structural schematic view of an array substrate completing the fabrication of a source and a drain electrode;

FIG. 13 is a sectional structural schematic view of an array substrate completing the fabrication of a passivation layer;

FIG. 14 is a sectional structural schematic view of an array substrate completing the fabrication of a pixel electrode;

FIG. 15 is a sectional structural schematic view of an array substrate completing the fabrication of a second passivation layer;

FIG. 16 is a flowchart schematic view of manufacturing the array substrate provided by the second embodiment; and

FIG. 17 is a flowchart schematic view of manufacturing a thin film transistor of the array substrate provided by the third embodiment.

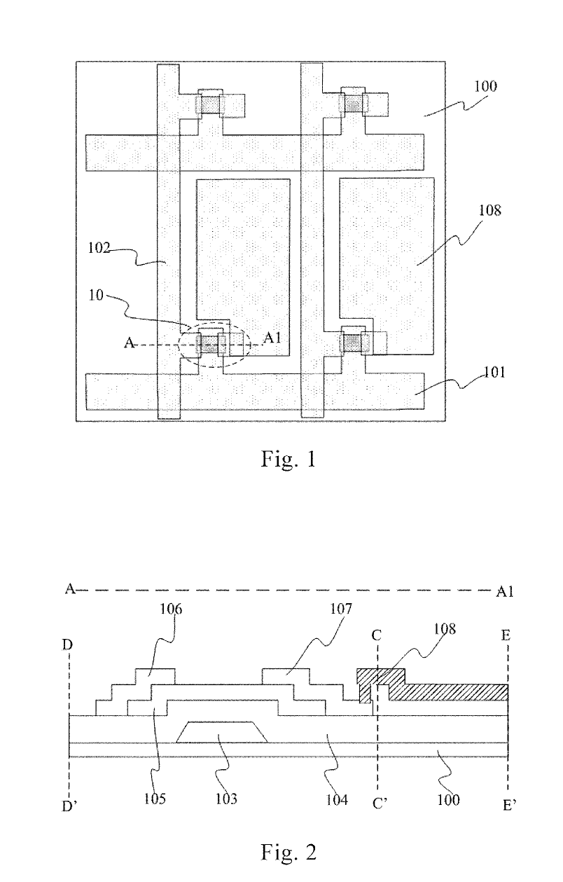

### DETAILED DESCRIPTION

The technical solutions in the embodiments of the present invention will be described clearly and completely below in connection with the figures in the embodiments of the present invention. Obviously, the described embodiments are only a portion of the embodiments of the present invention, not all the embodiments. Based on the embodiments in the present invention, all other embodiments, which can be obtained by those skilled in the art without giving creative labor, belong to the scope protected by the present invention.

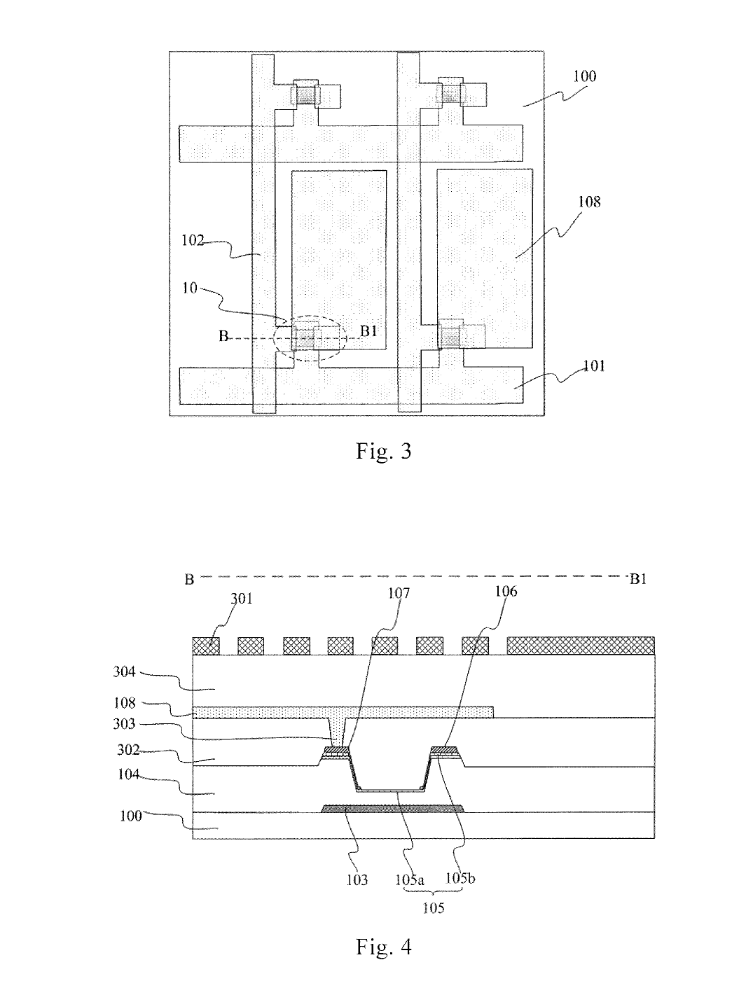

The first embodiment of the present invention provides an array substrate. FIG. 3 is a plan structural schematic view of an array substrate provided by the first embodiment of the present invention, and FIG. 4 is a sectional structural schematic view of the array substrate along a direction B-B1 in FIG. 3. Referring to FIGS. 3 and 4, the array substrate according to the first embodiment may comprise: a base substrate 100, a scan line 101 and a data line 102 disposed to cross each other on the base substrate, and thin film transistors 10 and pixel electrodes 108 arranged in a matrix. Each of the thin film transistors 10 may comprise: a gate electrode 103, a gate insulation layer 104, an active layer 105, a source electrode 106 and a drain electrode 107. The array substrate may further comprise a light emitting structure 301 above the pixel electrode 108, and the light emitting structure 301 is used to provide backlight source.

In particular, the gate electrode 103 may be disposed at the same layer as the scan line 101, both located above the base substrate 101, and the scan line 101 is used to provide scan signal to the gate electrode 103. The gate electrode 103 and the scan line 101 may be fabricated by using the same material, and the used materials are generally chromium (Cr), tungsten (W), titanium (Ti), molybdenum (Mo), aluminum (Al), copper (Cu), other opaque metals and their alloy.

The gate insulation layer 104 may be located on the layer where the gate electrode 103 and the scan line 101 are located, and covers the region over the gate electrode 103 and the scan line 101, and used to insulate the gate electrode 103 and the scan line 101 from other layers. The gate insulation layer may be formed by using silicon oxide or silicon nitride material with a thickness of 6000˜80001, which is about two times of the thickness of the gate insulation layer in the prior art. Increasing the thickness of the gate insulation layer 104 may effectively reduce the coupling capacitance between the gate electrode 103 and the source/drain electrodes 106 and 107 of the thin film transistor, and reduce power consumption of the thin film transistor.

The active layer 105 may be located on the gate insulation layer 104, and the active layer 105 is of a film layer structure, and in particular may comprise a semiconductor material layer 105a and an ohmic contact layer 105b. In some embodiments, the semiconductor material layer 105a may be formed of indium gallium zinc oxide or other transition metal oxide layers. In addition, the semiconductor material layer 105a may also be formed of amorphous silicon material or poly silicon material. The ohmic contact layer 105b may be disposed above the semiconductor material layer 105a and at the position corresponding to the source electrode 106 and the drain electrode 107, and is generally formed of amorphous silicon material doped with phosphorus.

The source electrode 106 and the drain electrode 107 may be disposed at the same layer as the data line 102, and both are located above the layer where the active layer 105 is located, and are fabricated by using the same material, and the used material is generally opaque metal materials or their alloy. The data line 102 may be electrically connected with the source electrode 106. The source electrode 106 and the drain electrode 107 may be positioned at two opposite sides above the active layer 105.

The pixel electrode 108 may be located above the layer where the data line 102, the source electrode 106 and the drain electrode 107 are located, the region covered by it comprises the region over the thin film transistor, and the pixel electrode 108 partially or entirely covers the non-light-transmitting region. The pixel electrode 108 is generally fabricated by using indium tin oxide, indium zinc oxide or aluminum zinc oxide and other transparent oxide materials, and its shape may be plate shape or slit shape.

The light emitting structure 301 may be located above the pixel electrode 108, and is disposed to be insulated from the pixel electrode 108, and the light emitting structure 301 may be slit shape, and is used to provide backlight source; meantime, the light emitting structure 301 may further function as the common electrode of the array substrate, and is used to form a horizontal electrical field together with the pixel electrode 108, to drive the liquid crystal molecules of the liquid crystal layer to rotate, so as to achieve wide angle displaying.

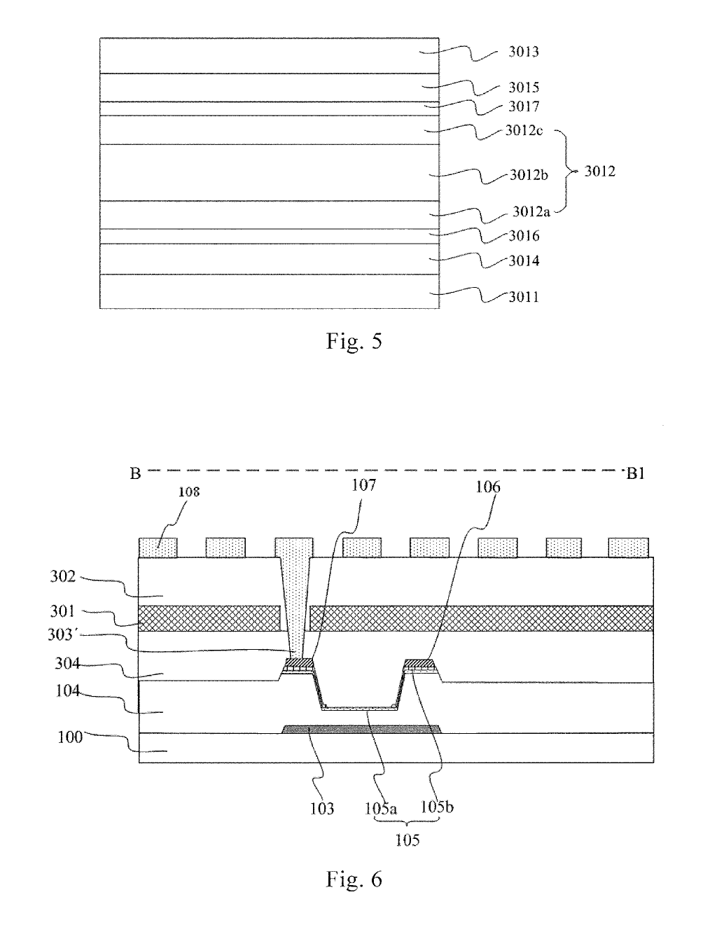

Referring to FIG. 5, the light emitting structure 301 may comprise: a cathode 3011, disposed above the pixel electrode 108; a light emitting material layer 3012, disposed above the cathode 3011; and an anode 3013, disposed above the light emitting material layer 3012. The anode 3013 may be connected with the common electrode line of the array substrate. The cathode 3011 and the anode 3013 are used to provide driving voltage to the light emitting structure, so that the light emitting structure generates white light.

In addition, the light emitting structure 301 may further comprise: an electron transporting layer 3014, between the cathode 3011 and the light emitting material layer 3012, and used to guide electrons into the light emitting material layer 3012; a hole transporting layer 3015, between the light emitting layer 3012 and the anode 3013, used to guide the holes into the light emitting material layer 3012; a first blocking layer 3016, between the electron transporting layer 3014 and the light emitting material layer 3012, used to block the holes from transporting to the cathode 3011; and a second blocking layer 3017, between the hole transporting layer 3015 and the light emitting material layer 3012, used to block the electrons from transporting to the anode 3013.

The light emitting material layer 3012 may comprise: an orange phosphor layer 3012a, on the first blocking layer 3016; a blue fluorescence layer 3012b, on the orange phosphor layer 3012a; and a green phosphor layer 3012c, on the blue fluorescence layer 3012b.

Upon the light emitting structure operating, electrons are injected from the cathode 3011 and holes are injected from the anode 3013, and the electrons are guided into the light emitting material layer 3012 by the electron transporting layer 3014, and holes are guided into the light emitting material layer 3012 by the hole transporting layer 3015, and electrons and holes are recombined in the light emitting material layer 3012, form singlet state excitons and triplet state excitons, during the process that singlet state excitons and triplet state excitons transfer from an excited state to a ground state, its energy is released in the manner of photon and heat energy, wherein portion of the photons are used as backlight source, to provide light ray for displaying of the image. In particular, in the blue fluorescence layer 3012b, when the singlet state excitons are transmitted from the excited state to the ground state, blue fluorescent light may be emitted; in the orange phosphor layer 3012a and the green phosphor layer 3012c, when the triplet state excitons are transmitted from the excited state to the ground state, green phosphorescent light and orange phosphorescent light may be emitted, and the blue fluorescent light is mixed with the green phosphorescent light and orange phosphorescent light, so as to form white light.

Further, the array substrate may further comprise a passivation layer 302, and the passivation layer 302 is disposed above the layer where the data line 102, the source electrode 106 and the drain electrode 107 are located, covers the region over the thin film transistor 10, so as to make it possible to form the pixel electrode above the thin film transistor, and meantime, used to protect the thin film transistor 10 form being corroded.

In addition, a via hole 303 may be further disposed in the passivation layer 302, and the via hole 303 may be disposed at the position corresponding to the drain electrode 107, so that the pixel electrode 108 and the drain electrode 107 may be electrically connected by the via hole 303.

Further, the array substrate may further comprise a second passivation layer 304, and the second passivation layer 304 is disposed above the layer where the pixel electrode 108 is located, and is used to isolate the pixel electrode 108 from the light emitting structure 301. The second passivation layer 304 may be formed by using resin material, compared with silicon oxide and silicon nitride materials, the resin material has a relatively lower dielectric constant, it may effectively reduce the coupling capacitance between the gate electrode and the source/drain electrode of the thin film transistor, to further reduce power consumption of the array substrate; moreover, compared with silicon oxide and silicon nitride materials, it is easier to form the second passivation layer by using the resin material.

The above array substrate may have the following driving process:

applying positive bias voltage on the gate electrode 103, so that the thin film transistor is turned on, the data signal is transmitted from the source electrode 106 of the thin film transistor to the drain electrode 107 of the thin film transistor, and is transmitted to the pixel electrode 108 by the via hole 303;

applying voltage on the light emitting structure 301, to make it emit white light;

when the light emitting structure 301 is electrified, it is equivalent to the common electrode of the array substrate, and couples with the pixel electrode 108 therebelow, to generate the electric field used to drive the liquid crystal molecules rotate, so as to achieve wide-angle displaying.

FIG. 6 illustrates an array substrate according to a second embodiment of the present invention. Referring to FIG. 6, the structure of the array substrate of the second embodiment may be substantially the same as the structure of the array substrate of the first embodiment, and different from it in that: in the array substrate provided by the second embodiment, the light emitting structure 301 may be disposed under the pixel electrode 108, and the light emitting structure 301 may be of plate shape or slit shape and the pixel electrode 108 may be of slit shape. In particular, the second passivation layer 304 is located on the layer where the thin film transistor is located, the light emitting structure 301 is disposed on the second passivation layer 304, the passivation layer 302 is disposed on the light emitting structure 301, the pixel electrode 108 is electrically connected with the drain electrode 107 by the via hole 303′, and the via hole 303′ penetrates the passivation layer 302 and the second passivation layer 304.

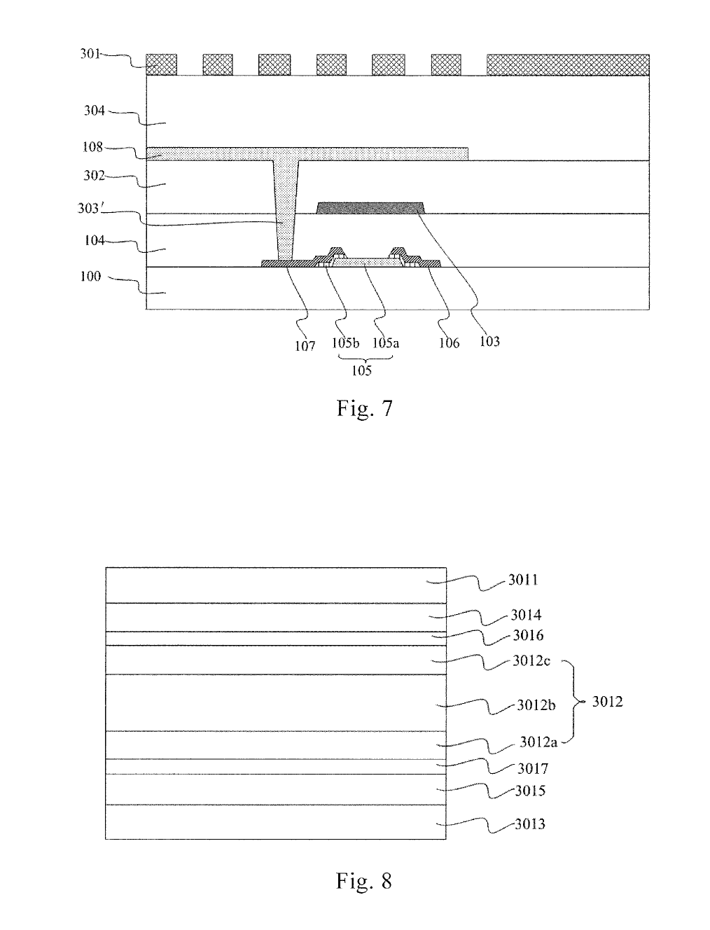

FIG. 7 illustrates an array substrate according to a third embodiment of the present invention. Referring to FIG. 7, the structure of the array substrate according to the third embodiment is substantially the same as the structure of the array substrate illustrated in FIG. 4, and different from it in that: the array substrate illustrated in FIG. 4 is an array substrate of bottom-gate structure, while the array substrate illustrated in FIG. 7 is an array substrate of top-gate structure. In particular, the active layer 105 is positioned on the base substrate 100; the source electrode 106, the drain electrode 107 and the data line are disposed at the same layer, and on the active layer 105; the gate insulation layer 104 is located on the layer where the source electrode 106 and the drain electrode 107 are located; the gate electrode 103 is located on the gate insulation layer 104; in the array substrate illustrated in FIG. 4, the via hole 303 only penetrates the passivation layer 302, while in the array substrate illustrated in FIG. 7, the via hole 303′ used to electrically connect the drain electrode 107 and the pixel electrode 108 penetrates the passivation layer 302 and the gate insulation layer 104.

It is to be noted that with respect to the array substrate provided by the third embodiment of the present invention, the light emitting structure 301 may be disposed under the pixel electrode 108, and it is not repeated here.

The fourth embodiment of the present invention provides an array substrate, and the array substrate has substantially the same structure as that of the array substrate illustrated in FIG. 4, and differs from it in that: the light emitting structure in the array substrate according to the fourth embodiment has different structure from that of the light emitting structure in the array substrate illustrated in FIG. 4. In particular, referring to FIG. 8, in the light emitting structure of the array substrate of the fourth embodiment, the hole transporting layer 3015 is disposed on the anode 3013, the second blocking layer 3017 is disposed on the hole transporting layer 3015, the light emitting material layer 3012 is disposed on the second blocking layer 3017, the first blocking layer 3016 is disposed on the light emitting material layer 3012, the electron transporting layer 3014 is disposed on the first blocking layer 3016, and the cathode 3011 is disposed on the electron transporting layer 3014. The anode 3013 generally adopts multiple layer structure of indium tin oxide/silver/indium tin oxide, and the cathode 3011 generally adopts transparent low work function alloy materials such as magnesium silver alloy, lithium aluminum alloy and so on.

In the same way, with respect to the array substrate provided by the fourth embodiment of the present invention, the light emitting structure 301 may be also disposed under the pixel electrode 108, and it is not repeated here.

The fifth embodiment of the present invention provides an array substrate, and the array substrate has substantially the same structure as that of the array substrate illustrated in FIG. 7, and differs from it in that: the light emitting structure in the array substrate of the fifth embodiment has different structure from that of the light emitting structure in the array substrate illustrated in FIG. 7, and the detailed structure may be referred to FIG. 8. In the same reason, in the array substrate provided by the fifth embodiment of the present invention, the light emitting structure 301 may be also disposed under the pixel electrode 108, and it is not repeated here.

In the array substrates provided by the above first to fifth embodiments, the region covered by the pixel electrode comprise a region over the thin film transistor and the light emitting structure is used to provide a backlight source. Since the region covered by the pixel electrode comprises the region over the thin film transistor, the region covered by the pixel electrode is increased compared with a region covered by the pixel electrode in the prior art, meantime, since the light emitting structure functions as a backlight source, it cause that there is light ray passing through the region corresponding to the pixel electrode located over the thin film transistor, which improves the aperture ratio of the pixel; in addition, the light emitting structure may further function as a common electrode of the array substrate, and form a horizontal electrical field used to drive the liquid crystal molecules together with the pixel electrode, so as to achieve wide angle displaying.

An embodiment of the present invention further provides a method of manufacturing an array substrate, and the method may comprise: a step of farming a data line, a scan line and a pixel electrode and a step of forming a thin film transistor, wherein the pixel electrode is formed in a light-transmitting region of a pixel unit, and the thin film transistor, the scan line and the data line are formed in the non light-transmitting region, wherein the pixel electrode is located above the layer where the thin film transistor is located, and the pixel electrode partially or entirely covers the non-light-transmitting region; a step of forming a light emitting structure, wherein the light emitting structure is located above the layer where the thin film transistor is located, and is disposed to be insulated from the pixel electrode, and a region covered by the light emitting structure corresponds to a region covered by the pixel electrode, and is used to provide a backlight source.

The following will give a detailed description on actual manufacturing process by taking the array substrate provided by the first embodiment of the present invention, and the manufacturing method of the array substrate may comprise in particular:

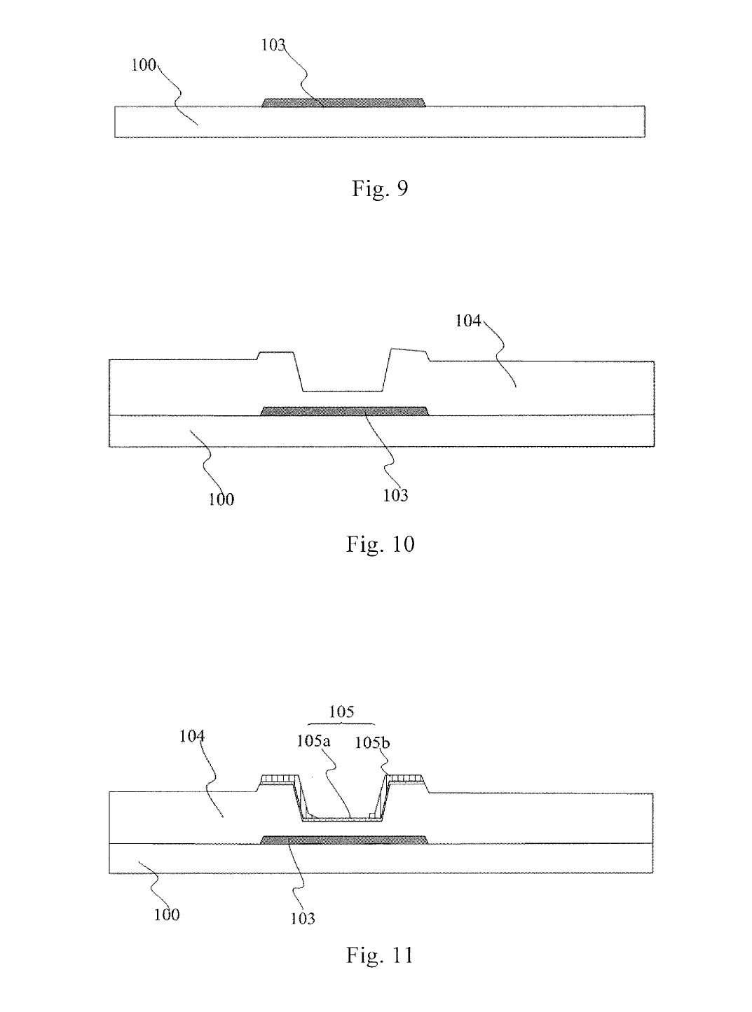

First step, referring to FIG. 9, a layer of metal thin film is deposited on the base substrate 100, and a pattern comprising the scan line and the gate electrode 103 is formed by patterning process treatment, wherein the material used to form metal thin film may be Cr, W, Ti, Ta, Mo, Al, Cu, other opaque metals and their alloy.

Second step, referring to FIG. 10, a silicon nitride or silicon oxide layer is deposited above the pattern comprising the scan line and the gate electrode 103, to form the gate insulation layer 104.

This step may comprise in detail: depositing a silicon nitride or silicon oxide layer above the pattern comprising the scan line and the gate electrode 103, wherein its thickness is 6000˜8000 Å, which is about two times of the thickness of the gate insulation layer in the prior art; coating photoresist on the silicon nitride or silicon oxide layer; removing portion of the silicon nitride or silicon oxide corresponding to the channel region, so that the thickness of the gate insulating layer corresponding to the conductive channel region is the same as that of the gate insulating layer corresponding to the conductive channel region in the prior art, so as to ensure a relatively high on state current.

Third step, referring to FIG. 11, semiconductor material and amorphous silicon material doped with phosphorus are sequentially deposited on the gate insulation layer 104, and a pattern comprising the active layer 105 is formed by patterning process. The semiconductor material may be poly silicon semiconductor material, amorphous silicon semiconductor material or metal oxide semiconductor material.

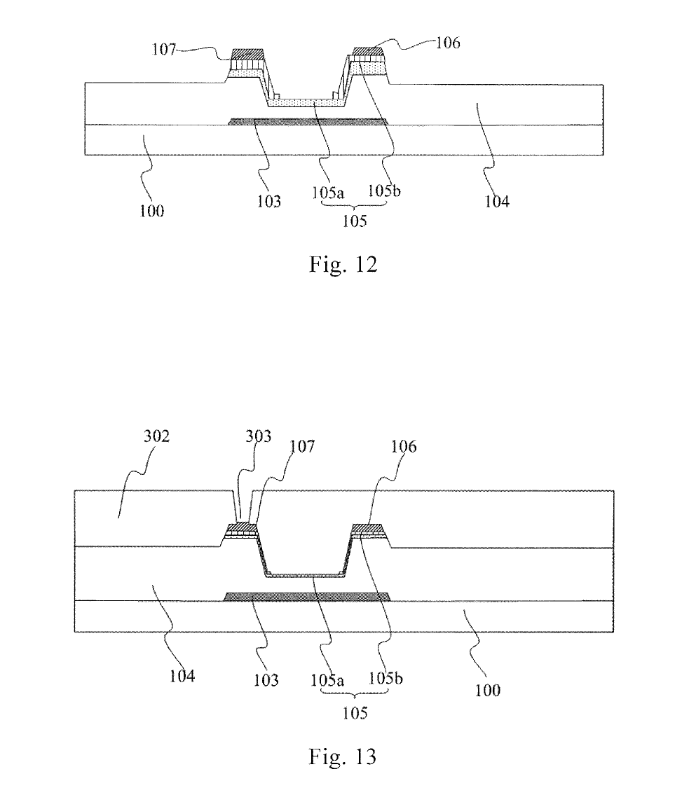

Fourth step, referring to FIG. 12, a source and drain metal thin film is formed on the pattern comprising the active layer 105, and a pattern comprising the data line, the source electrode 106 and the drain electrode 107 is foamed by patterning process.

Fifth step, referring to FIG. 13, a silicon nitride or silicon oxide layer is deposited on the pattern comprising the data line, the source electrode 106 and the drain electrode 107 to form the passivation layer 302, so as to make it possible to form the pixel electrode above the thin film transistor and be used to protect the thin film transistor from being corroded; and a via hole 303 is formed in the passivation layer 302 by patterning process, wherein the via hole 303 penetrates the passivation layer 302 and corresponds to the position of the drain electrode 107.

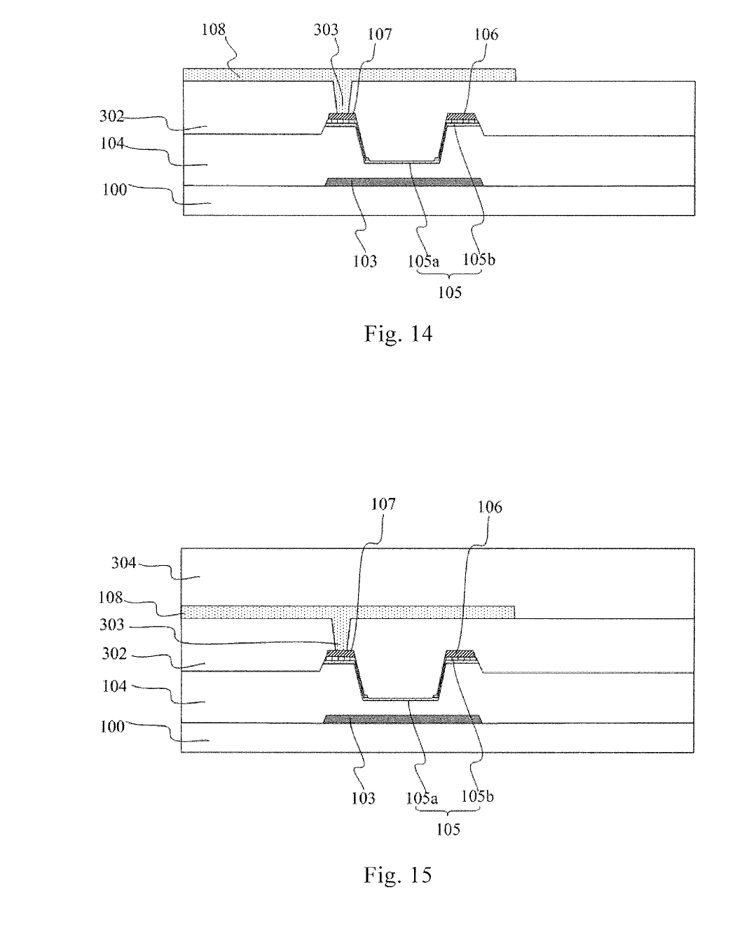

Sixth step, referring to FIG. 14, a layer of indium tin oxide transparent conductive thin film is deposited above the passivation layer 302 by using magnetron controlled sputtering method, and a pattern comprising the pixel electrode 108 is formed by patterning process. The region covered by the pixel electrode 108 may comprise the region over the thin film transistor, and the pixel electrode partially or entirely covers the non-light-transmitting region of the pixel unit. Moreover, the pixel electrode 108 may be electrically connected with the drain electrode 107 by the via hole 303.

Seventh step, referring to FIG. 15, resin is spin coated above the pattern comprising the pixel electrode 108, to than the second passivation layer 304, which is sued to isolate the pixel electrode 108 from the light emitting structure 301. The second passivation layer may also be fabricated by using silicon oxide or silicon nitride materials; however, the resin material has relatively lower dielectric constant, and it may effectively reduce the coupling capacitance between the pixel electrode and the light emitting structure, to further reduce power consumption of the array substrate; moreover, since the resin material has flowing property, it is easier to form the second passivation layer compared with silicon oxide and silicon nitride materials.

Eighth step, referring to FIG. 4, conductive material with high reflectivity, light emitting material and transparent conductive material are sequentially deposited on the second passivation layer 304, and a pattern comprising the light emitting structure 301 is formed by patterning process. The light emitting structure 301 may be used to provide a backlight source, and meantime, may further function as a common electrode of the array substrate, to generate electrical field together with the pixel electrode to drive the liquid crystal molecules to rotate, to achieve image displaying. In particular, the step of forming the light emitting structure 301 may comprise: depositing a conductive material having high reflectivity on the passivation layer and forming a pattern comprising a cathode by patterning process; depositing light emitting material on the pattern comprising the cathode, and forming a pattern comprising the light emitting material layer by patterning process; depositing transparent conductive material on the pattern comprising the light emitting material layer, and foaming a pattern comprising the anode by patterning process.

The array substrate having a structure illustrated in FIG. 4 provided by the first embodiment is formed by the above steps.

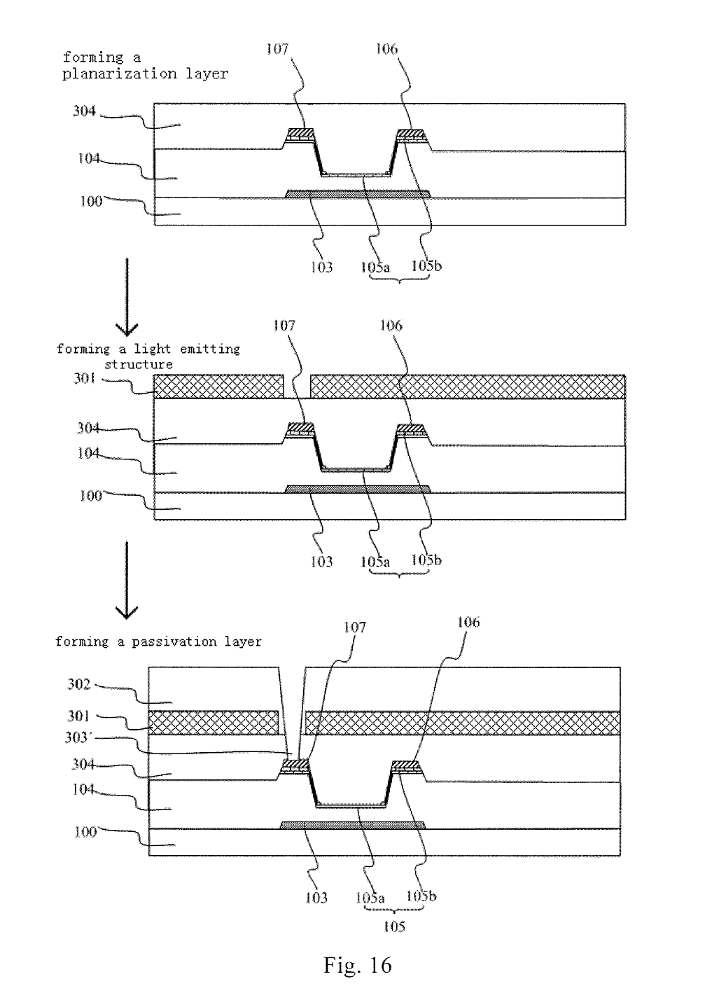

With respect to the array substrate, in which the light emitting structure is disposed under the pixel electrode, provided by the second embodiment of the present invention, its manufacturing method may be substantially the same as the method of manufacturing the array substrate provided by the first embodiment of the present invention, and differs from it in that: referring to FIG. 16, the method of manufacturing the array substrate provided by the second embodiment of the present invention may comprise:

spin coating resin on the pattern comprising the data line, the source electrode 106 and the drain electrode 107 to form the second passivation layer 304, to isolate the thin film transistor from the light emitting structure 301;

sequentially depositing conductive material having high reflectivity, light emitting material and transparent conductive material on the second passivation layer 304, and forming a pattern comprising the light emitting structure 301 by patterning process;

depositing silicon nitride or silicon oxide layer on the pattern comprising the light emitting structure 301 to foam the passivation layer 302;

depositing a layer of indium tin oxide transparent conductive thin film on the passivation layer 302 by using magnetron controlled sputtering method, and forming a pattern comprising the pixel electrode 108 by patterning process, wherein the region covered by the pixel electrode 108 may comprise the region over the thin film transistor; moreover, the pixel electrode 108 is electrically connected with the drain electrode 107 by the via hole 303′, and the via hole 303′ penetrates the passivation layer 302 and the second passivation layer 304.

The array substrate having a structure illustrated in FIG. 6 provided by the second embodiment of the present invention is formed by the above steps.

It is to be noted that, with respect to the array substrate in which the light emitting structure is disposed under the pixel electrode in the present invention, the second passivation layer, the light emitting structure, the passivation layer and the pixel electrode are sequentially formed after forming the thin film transistor, and the details may be referred to the method of manufacturing the array substrate according to the second embodiment.

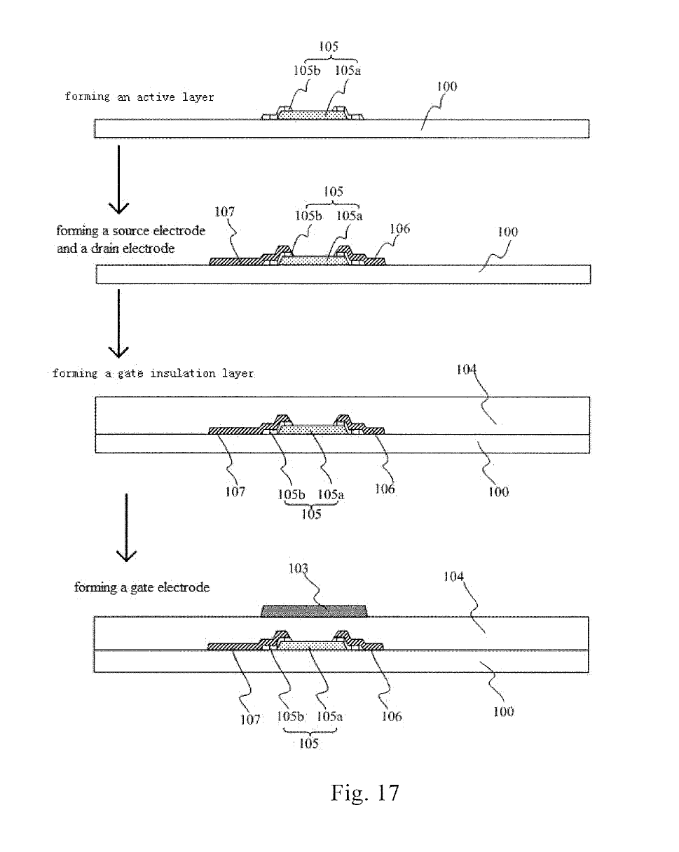

With respect to the array substrate provided by the third embodiment of the present invention, its manufacturing method is substantially the same as the method of manufacturing the array substrate according to the first embodiment of the present invention, and differs from it in that: referring to FIG. 17, when manufacturing the array substrate according to the third embodiment, the step of forming the thin film transistor may comprise:

depositing an amorphous silicon semiconductor material layer 105a and amorphous silicon material layer 105b doped with phosphorus on the base substrate 100, and forming a pattern comprising the active layer 105 by patterning process;

forming a source and drain metal thin film on the pattern comprising the active layer 105, and forming a pattern comprising the data line, the source electrode 106 and the drain electrode 107 by patterning process;

depositing silicon nitride or silicon oxide material on the pattern comprising the data line, the source electrode 106 and the drain electrode 107 to form the gate insulation layer 104;

depositing a layer of metal thin film on the gate insulation layer 104, and forming a pattern comprising the scan line and the gate electrode 103 by patterning process treatment, wherein the material used to form metal thin film may be Cr, W, Ti, Ta, Mo, Al, Cu, other opaque metal and their alloy.

With respect to the array substrate according to the fourth embodiment of the present invention, its manufacturing method is similar to the method of manufacturing the array substrate of the first embodiment of the present invention, and differs from it in that: when manufacturing the array substrate of the fourth embodiment, the step of forming the light emitting structure may comprise: depositing conductive material having high reflectivity on the passivation layer and forming a pattern comprising an anode by patterning process; depositing light emitting material on the pattern comprising the anode, and forming a pattern comprising the light emitting material layer by patterning process; depositing transparent conductive material on the pattern comprising the light emitting material layer, and forming a pattern comprising the cathode by patterning process.

With respect to the array substrate according to the fifth embodiment of the present invention, its manufacturing method is similar to the method of manufacturing the array substrate of the third embodiment of the present invention, and differs from it in that: when manufacturing the array substrate of the fifth embodiment, the step of forming the light emitting structure may be the same as the step of forming the light emitting structure when manufacturing the array substrate of the fourth embodiment.

It is to be noted that, in the embodiment of the present invention, the patterning process may only comprise photolithography process, or comprise photolithography process and etching step, meantime, may further comprise printing, inkjet and other processes to form predetermined pattern; the photolithography process refers to the process of forming a pattern by using photoresist, mask and exposure machine and so on, and comprises film formation, exposing, developing and other processes. Corresponding patterning process may be selected according to the formed structure in the embodiment of the present invention.

An embodiment of the present invention further provides a display apparatus, and the display apparatus comprises the above array substrate.

To sum up, in the array substrates provided by the embodiments of the present invention, since the region covered by the pixel electrode comprises a region over the thin film transistor, the region covered by the pixel electrode is increased compared with the region covered by the pixel electrode in the prior art, meantime, since the light emitting structure functions as a backlight source, it cause that there is light ray passing through the region corresponding to the pixel electrode located over the thin film transistor, and the region may perform image displaying, and it is advantageous to improve the aperture ratio of the pixel; meantime, since two electrodes are disposed in the light emitting structure, the driving of the light emitting structure is not dependent on the property of thin film transistor, so it solve the problem that amorphous silicon material could not be used to manufacture a display having a high resolution and high aperture ratio.

Obvious, those skilled in the art may performing various amendments and modifications to the present invention, without departing the spirit and scope of the present invention. Thus, if these amendments and modifications of the present invention belong to the scope of the claims of the present invention and its equivalent technology, the present invention is intended to cover these amendments and modifications.

1. An array substrate, comprising a plurality of pixel units arranged in a matrix, wherein each of the pixel unit comprises a light-transmitting region and a non-light-transmitting region, the light-transmitting region comprises a pixel electrode, and the non-light-transmitting region comprises a thin film transistor, a scan line and a data line,
wherein the pixel electrode is positioned above a layer where the thin film transistor is located, and the pixel electrode partially or entirely covers the non-light-transmitting region;
wherein each of the pixel units further comprises a light emitting structure which is disposed above the layer where the thin film transistor is located and is disposed to be insulated from the pixel electrode, and a region covered by the light emitting structure corresponds to a region covered by the pixel electrode, and the light emitting structure is used to provide a backlight source.

2. The array substrate according to claim 1, wherein the light emitting structure is connected with a common electrode line to function as a common electrode of the array substrate.

3. The array substrate according to claim 2, wherein the light emitting structure comprises a cathode, a light emitting material layer disposed on the cathode, and an anode disposed on the light emitting material layer, wherein the anode is connected to the common electrode line;
or, the light emitting structure comprises an anode, a light emitting material layer disposed on the anode, and a cathode disposed on the light emitting material layer, wherein the anode is connected to the common electrode line.

4. The array substrate according to claim 1, wherein the light emitting structure is located above the pixel electrode, wherein the light emitting structure is of slit shape, and the pixel electrode is of plate shape or slit shape;
or, the light emitting structure is located under the pixel electrode, the light emitting structure is of slit shape or plate shape, and the pixel electrode is of slit shape.

5. The array substrate according to claim 1, wherein the gate insulation layer of the thin film transistor has a thickness of about 6000˜8000 Å.

6. The array substrate according to claim 1, further comprising a passivation layer disposed between the layer where the thin film transistor is located and the pixel electrode.

7. The array substrate according to claim 1, further comprising a second passivation layer disposed between the pixel electrode and the light emitting structure.

8. The array substrate according to claim 6, wherein a via hole is formed at least in the passivation layer to electrically connect the pixel electrode to a drain electrode of the thin film transistor.

9. The array substrate according to claim 1, wherein the thin film transistor has a top-gate structure or a bottom-gate structure.

10. A display apparatus, comprising the array substrate according to claim 1.

11. A manufacturing method of an array substrate, comprising:
a step of forming a data line, a scan line and a pixel electrode and a step of forming a thin film transistor, wherein the pixel electrode is formed in a light-transmitting region of a pixel unit, and the thin film transistor, the scan line and the data line are formed in a non light-transmitting region, wherein the pixel electrode is located above a layer where the thin film transistor is located, and the pixel electrode partially or entirely covers the non-light-transmitting region; and
a step of forming a light emitting structure, wherein the light emitting structure is located above the layer where the thin film transistor is located, and is disposed to be insulated from the pixel electrode, and a region covered by the light emitting structure corresponds to a region covered by the pixel electrode.

12. The method according to claim 11, wherein the step of forming the light emitting structure comprises:
forming a pattern comprising a cathode, forming a pattern comprising a light emitting material layer on the pattern comprising the cathode, and forming a pattern comprising an anode on the pattern comprising the light emitting material layer;
or, forming a pattern comprising an anode, forming a pattern comprising a light emitting material layer on the pattern comprising the anode, and forming a pattern comprising a cathode on the pattern comprising the light emitting material layer.

13. The method according to claim 11, wherein the light emitting structure is located above the pixel electrode, the light emitting structure is of slit shape, and the pixel electrode is of plate shape or slit shape;
or, the light emitting structure is located under the pixel electrode, the light emitting structure is of slit shape or plate shape, and the pixel electrode is of slit shape.

14. The method according to claim 11, further comprising:
forming a passivation layer between the layer where the thin film transistor is located and the pixel electrode.

15. The method according to claim 11, further comprising:
forming a second passivation layer between the pixel electrode and the light emitting structure.

16. The array substrate according to claim 2, wherein the light emitting structure is located above the pixel electrode, wherein the light emitting structure is of slit shape, and the pixel electrode is of plate shape or slit shape;
or, the light emitting structure is located under the pixel electrode, the light emitting structure is of slit shape or plate shape, and the pixel electrode is of slit shape.

17. The array substrate according to claim 2, wherein the gate insulation layer of the thin film transistor has a thickness of about 6000˜8000 Å.

18. The array substrate according to claim 2, further comprising a passivation layer disposed between the layer where the thin film transistor is located and the pixel electrode.

19. The array substrate according to claim 2, further comprising a second passivation layer disposed between the pixel electrode and the light emitting structure.

20. The array substrate according to claim 2, wherein the thin film transistor has a top-gate structure or a bottom-gate structure.
